(19) United States
(12) Patent Application Publication
(10) Pub. No.: US 2010/0178744 A1
(43) Pub. Date: Jul. 15, 2010

(54) MANUFACTURE METHOD FOR SEMICONDUCTOR DEVICE WHOSE GATE INSULATING FILM CONTAINS Hf AND O

(75) Inventors: Haruhiko Takahashi, Shinjuku (JP); Hiroshi Minakata, Shinjuku (JP); Naoyoshi Tamura, Shinjuku (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/646,233

(22) Filed: Dec. 23, 2009

(30) Foreign Application Priority Data
Jan. 13, 2009 (JP) 2009-004241

(51) Int. Cl. H01L 21/336

(52) U.S. Cl. 438/287; 438/301; 257/E21.409; 257/E21.423

(57) ABSTRACT

An insulating film having Hf and O is formed over a semiconductor substrate. A cap film having oxygen and titanium as constituent elements is formed over the insulating film. The insulating film and cap film are thermally treated in a nitrogen gas or noble gas to diffuse titanium in the cap film into the insulating film to form a gate insulating film. A gate electrode film is formed over the gate insulating film.

### CROSS-REFERENCE TO RELATED APPLICATION

This application is based upon and claims the benefit of priority of the prior Japanese Patent Application No. 2009-004241 filed on Jan. 13, 2009, the entire contents of which are incorporated herein by reference.

### FIELD

The embodiments discussed herein are related to a manufacture method for a semiconductor device whose gate insulating film contains Hf and O.

### BACKGROUND

In order to thin an equivalent oxide film thickness (EOT) of a gate insulating film, hafnium-based oxide is used, a dielectric constant of which is higher than that of silicon oxide. Further, a metal gate electrode is adopted in place of conventional polysilicon in order to prevent a gate electrode from being depleted and to lower a gate resistance.

High speed calculation MOSFETs used in a super computer and the like require a low threshold voltage. For example, threshold voltages of high speed calculation pMOSFET and nMOSFET are set to about −100 to −200 meV and about 100 to 200 meV, respectively. An apparent work function of the gate electrode moves near to 4.5 eV (approximately the center of a silicon forbidden band), if hafnium-based oxide is used as a gate insulating film, and TiN, TaN, Ta or the like is, for example, used as a metal gate electrode, and high temperature thermal treatment is performed. Therefore, an absolute value of a flat band voltage becomes small so that it becomes difficult to obtain a low threshold voltage. It is known that it becomes possible to make small an absolute value of a threshold voltage if an alumina (Al₂O₃) film is disposed on a hafnium-based oxide film used as a gate insulating film of pMOSFET, and heating and diffusion are conducted.

[Patent Document 1] Japanese Laid-open Patent Publication 2007-67266

[Non-Patent Document 1] H. Arimura et al., “Structural Optimization of HfTiSiO High-k Gate Dielectrics by Utilizing In-Situ PVD-based Fabrication Method”, Fifth International Symposium on Control of Semiconductor Interfaces (ISCSI-V), Nov. 12 to 14, 2007

### SUMMARY

A dielectric constant of alumina is lower than that of hafnium-based oxide. Therefore, as the alumina film is stacked on a gate insulating film made of hafnium-based oxide, it becomes difficult to thin an equivalent oxide film thickness. Al diffusion lowers a mobility of holes in the channel.

Accordingly, it is an object in one aspect of the embodiment to provide a manufacture method for a semiconductor device, including:

forming an insulating film containing Hf and O over a semiconductor substrate;

forming a cap film containing oxygen and titanium as constituent elements over the insulating film;

thermally treating the insulating film and the cap film in a nitrogen gas or noble gas to diffuse titanium in the cap film into the insulating film to form a gate insulating film; and

forming a gate electrode film over the gate insulating film.

It is an object in another aspect of the embodiment to provide a manufacture method for a semiconductor device, including:

forming an insulating film containing Hf and O over a semiconductor substrate;

forming a cap film of titanium over the insulating film;

thermally treating the insulating film and the cap film in an atmosphere containing oxygen gas and ammonia gas to diffuse titanium in the cap film into the insulating film to form a gate insulating film; and

forming a gate electrode film over the gate insulating film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A to 1H are cross sectional views of a semiconductor device during manufacture using a method according to a first embodiment, and FIG. 1I is a cross sectional view of a semiconductor device manufactured by the method of the first embodiment.

FIG. 2 is a graph illustrating measurement results of channel mobilities of semiconductor devices manufactured by the embodiment method and comparative example methods.

FIG. 3 is a graph illustrating measurement results of flat band voltages of semiconductor devices manufactured by the embodiment method and comparative example methods.

FIGS. 4A to 5C are cross sectional views of a semiconductor device during manufacture using a method according to a second embodiment.

### DESCRIPTION OF EMBODIMENTS

With reference to the accompanying drawings, the first and second embodiments will be described.

### First Embodiment

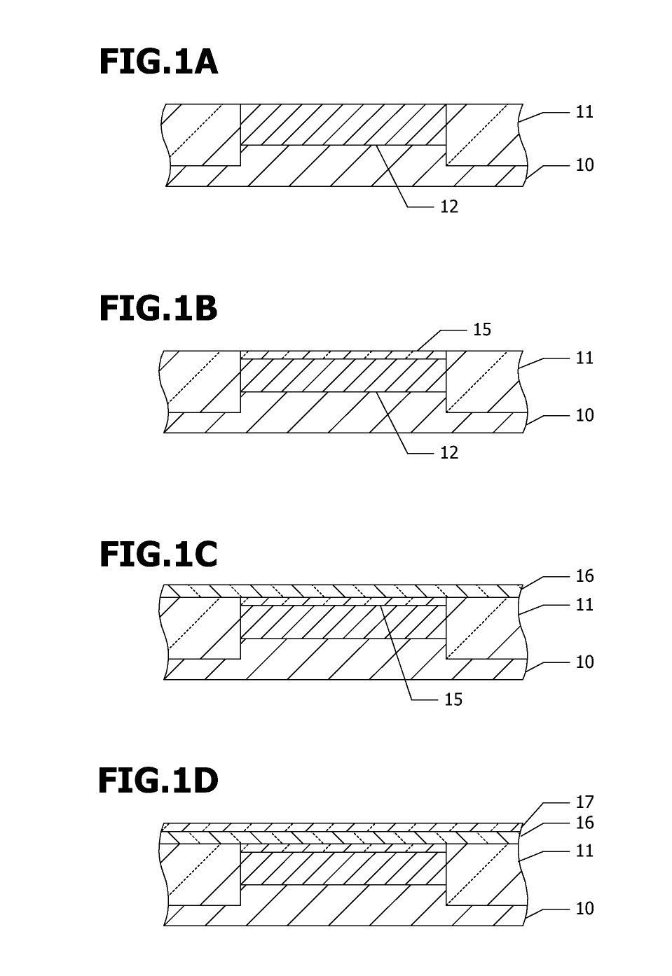

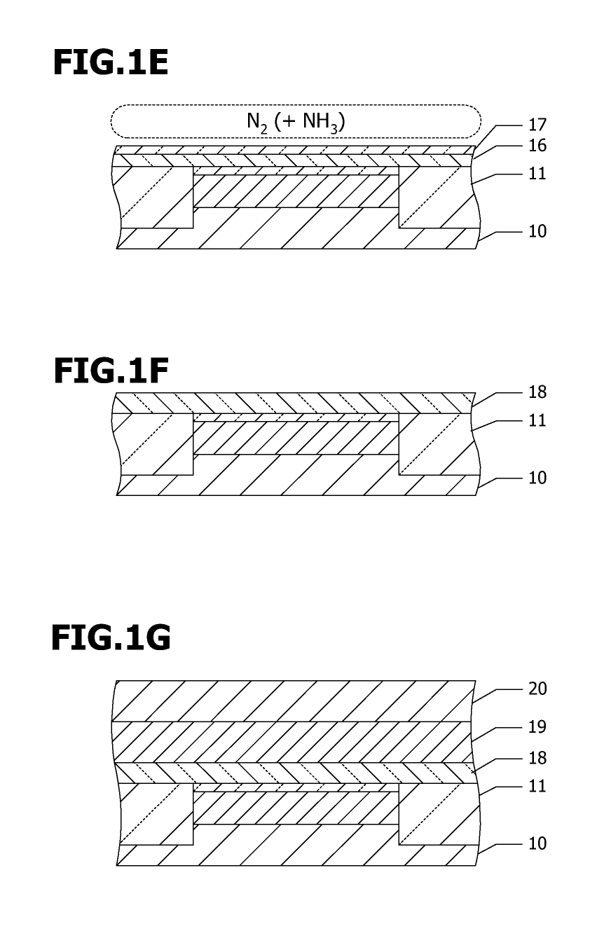

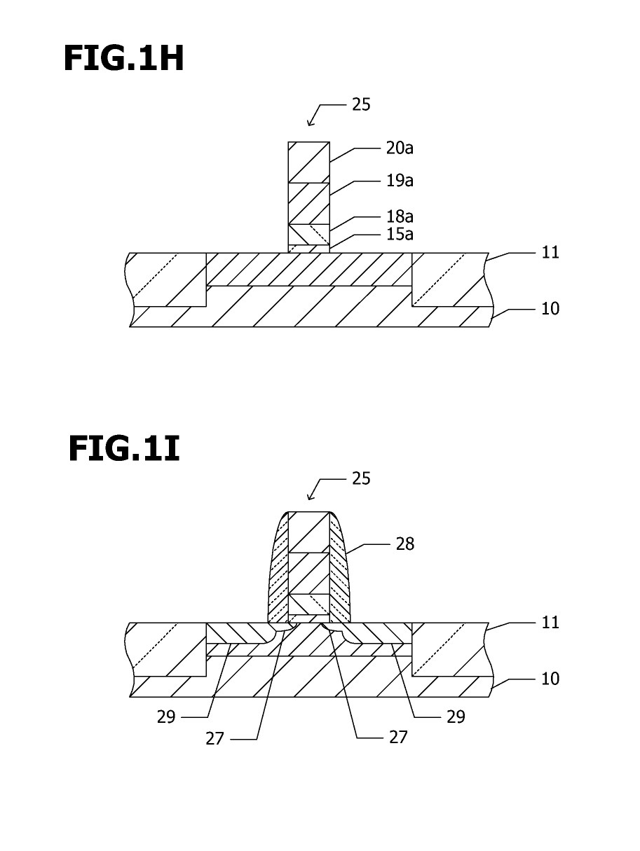

With reference to FIGS. 1A to 1I, the manufacture method for a semiconductor device of the first embodiment will be described.

As illustrated in FIG. 1A, an element isolation insulating film 11 is formed by shallow trench isolation (STI) in a surface layer of a semiconductor substrate 10 made of silicon. The device isolation insulating film 11 defines active regions. Channel dopant ions are implanted into an active region to form a channel dopant diffusion region 12.

As illustrated in FIG. 1B, a first gate insulating film 15 of silicon oxide having a thickness of 0.3 nm to 1 nm is formed on the surface of the active region, by thermal oxidation. The thermal oxidation conditions are, for example, as follows:

| | |
|---|---|
| Atmosphere | oxygen 100% |
| Pressure | 13 Pa to 1.0 × 10⁵ Pa |
| Film forming temperature | 500° C. to 1000° C. |
| Film forming time | 1 sec to 100 sec |

After the silicon oxide film is formed, plasma nitridation may be performed to form the first gate insulating film of silicon oxynitride.

As illustrated in FIG. 1C, an insulating film 16 having a thickness of 1 nm to 2 nm is formed on the first gate insulating film 15 and element isolation insulating film 11. The insulating film 16 is made of insulating material containing hafnium (Hf) and oxygen (O), e.g., hafnium oxide (HfO₂). The insulating film 16 is formed by chemical vapor deposition (CVD), atomic layer deposition (ALD), reactive sputtering or the like. The conditions of forming the insulating film 16 by CVD are, for example, as follows:

| | |
|---|---|
| Hafnium raw material | tetrakis-diethyl-amino-hafnium |
| Oxidant | oxygen, ozone, or H₂O |
| Film forming temperature | 400° C. to 700° C. |

As illustrated in FIG. 1D, a cap film 17 of titanium oxide (TiO₂) having a thickness of 0.3 nm to 2 nm is formed on the insulating film 16, for example, using reactive sputtering. The film forming conditions are, for example, as follows:

| | |
|---|---|
| Sputtering gas | mixture gas of O₂ and Ar |
| Pressure | 1.3 × 10⁻³ Pa to 133 Pa |
| Film forming temperature | room temperature |

As illustrated in FIG. 1E, thermal treatment for the insulating film 16 and cap film 17 is performed in a nitrogen gas atmosphere. The thermal treatment conditions are, for example, as follows:

| | |
|---|---|
| Pressure | 13 Pa to 133 Pa |
| Film forming temperature | 400° C. to 800° C. |
| Film forming time | 5 sec to 30 sec |

The thermal treatment may be performed in an atmosphere of noble gas such as Ar, instead of nitrogen gas. Ammonia gas may be added to the thermal treatment atmosphere. In this case, an ammonia gas partial pressure ratio is set to, for example, 0.1% to 1%.

As illustrated in FIG. 1F, since Ti in the cap film 17 is diffused into the insulating film 16 by thermal treatment, the insulating film 16 and cap film 17 are replaced with a second gate insulating film 18 of HfTiO. If ammonia gas is added to the thermal treatment atmosphere, a second gate insulating film 18 of HfTiON is formed.

As illustrated in FIG. 1G, a metal gate electrode film 19 having a thickness of 5 nm to 20 nm is formed on the second gate insulating film 18. The material of the metal gate electrode film 19 is, for example, TiN, TiAlN, TaN, TaAlN, TaCN or the like. The metal gate electrode film 19 made of each of these materials is formed by, for example, reactive sputtering. The conditions of forming the TiN film by reactive sputtering are, for example, as follows:

| | |
|---|---|
| Sputtering gas | mixture gas of N₂ and Ar |
| Pressure | 1.3 × 10⁻³ Pa to 133 Pa |
| Power | 100 W to 400 W |

A polysilicon film 20 is formed on the metal gate electrode film 19 using CVD or the like.

As illustrated in FIG. 1H, the first gate insulating film 15, second gate insulating film 18, gate electrode film 19 and polysilicon film 20 are patterned to form a gate pattern 25. The gate pattern 25 has a lamination structure of a first gate insulating film 15a of silicon oxide, a second gate insulating film 18a of HfTiO, a metal gate electrode 19a of metal such as TiN and a polysilicon film 20a, which are stacked in recited order.

As illustrated in FIG. 1I, by using the gate pattern 25 as a mask, p-type dopant ions are implanted into the surface layer of the semiconductor substrate 10 on either side of the gate pattern 25 to form source and drain extension regions 27. Side wall spacers 28 are formed on the side walls of the gate pattern 25. By using the gate pattern 25 and side wall spacers 28 as a mask, p-type dopant ions are implanted in the surface layer of the semiconductor substrate 10 on either side of gate pattern 25 and the side wall spacers 28 to form source and drain regions 29. After dopant implantation, annealing is performed to activate the dopants.

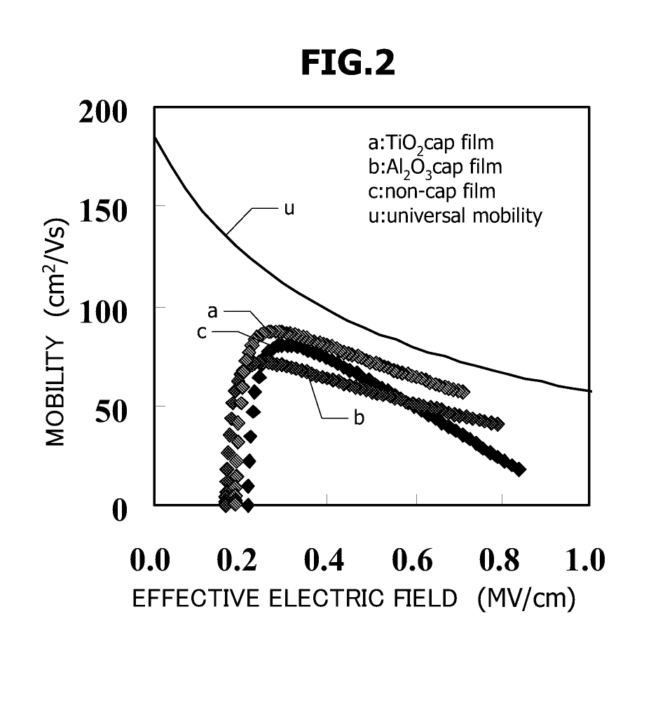

FIG. 2 illustrates a measurement result of a channel mobility of a sample a manufactured by the method of the first embodiment. TiN was used as the gate electrode. For comparison, FIG. 2 illustrates also measurement results of mobilities of a sample b using Al₂O₃ as the cap film and a sample c without a cap film. A universal mobility is indicated by a solid line u. The abscissa represents an effective electric field in the unit of “MV/cm”, and the ordinate represents a mobility in the unit of “cm²/Vs”.

A mobility of the sample b in which Al₂O₃ is used as the cap film 17 is lower than that of the sample c in which the cap film 17 is not formed. A mobility of the sample a in which TiO₂ is used as the cap film 17 is higher than that of the sample c. By using TiO₂ as the cap film 17, it is possible to prevent deterioration of a mobility which would occur when Al₂O₃ is used as the cap film 17.

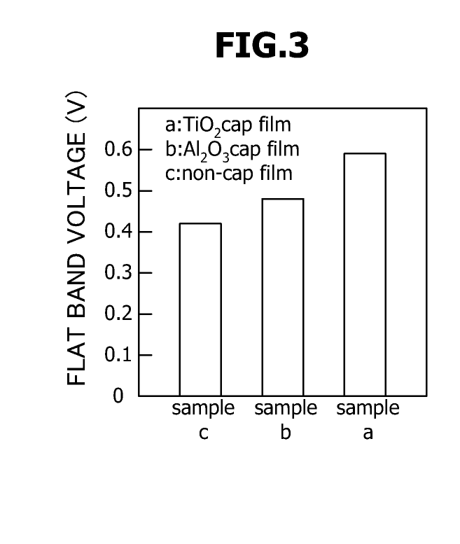

FIG. 3 illustrates measurement results of flat band voltages of the samples a, b and c. A flat band voltage being higher means a threshold value of pMOSFET being higher (an absolute value of a negative threshold value being smaller). It is noted that as the cap film 17 is formed, a flat band voltage shifts in a positive direction compared to the case where the cap film 17 is not formed. As TiO₂ is used as the cap film 17, the flat band voltage shifts more significantly compared to the case of Al₂O₃. It is noted from these evaluation results that it is possible to make the absolute value of the threshold voltage of pMOSFET small by adopting the method of the first embodiment.

A relative dielectric constant of TiO₂ is about 50 to 60 which is larger than a relative dielectric constant of Al₂O₃ which is about 12. A dielectric constant of HfTiO is higher than that of HfAlO. Therefore, as TiO₂ is used as the cap film 17, it is possible to thin the equivalent oxide film thickness of the second gate insulating film 18 compared to the case of Al₂O₃.

In the first embodiment, an atmosphere during thermal treatment illustrated in FIG. 1E does not contain oxidizing gas. Generally, if Ti is used as the cap film 17 instead of TiO₂ and thermal treatment is performed in a nitrogen atmosphere, defects caused by oxygen deficiency are generated in the second gate insulating film 18. In the first embodiment, since the cap film 17 contains oxygen as its constituent element, defect generation by oxygen deficiency is suppressed. If thermal treatment is performed in an O₂ atmosphere in order to prevent oxygen deficiency, oxygen diffuses to the first gate insulating film 15 illustrated in FIG. 1E to increase its thickness. With the method of the first embodiment, it is possible to suppress an increase in a thickness of the first gate insulating film 15 during thermal treatment.

If ammonia is added to the atmosphere of thermal treatment illustrated in FIG. 1E, the second gate insulating film 18 contains nitrogen and is made of HfTiON. Since a dielectric constant of HfTiON is higher than that of HfTiO, it is possible to further thin the equivalent oxide film thickness of the second gate insulating film 18.

The insulating film 16 illustrated in FIG. 1C is made of HfO₂ and does not contain Si. If the insulating film 16 contains Si, Si is gathered on the surface so that SiO₂ is likely to be formed. If an SiO₂ film is formed, the equivalent oxide film thickness increases because a dielectric constant of SiO₂ is lower than those of HfO₂ and TiO₂. Since the insulating film 16 of the first embodiment does not contain Si, Si is able to be prevented from being gathered during thermal treatment.

### Second Embodiment

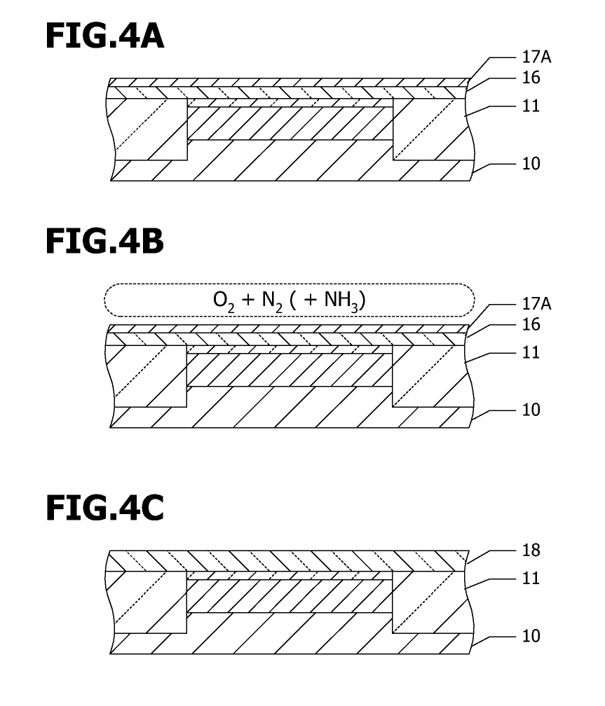

With reference to FIGS. 4A to 4C, description will be made on a manufacture method for a semiconductor device of the second embodiment.

The processes until forming the insulating film 16 illustrated in FIG. 4A are common to processes of the first embodiment illustrated in FIG. 1C. In the first embodiment, TiO₂ was used as the cap film 17, whereas in the second embodiment, metal titanium is used as a cap film 17A. A thickness of the cap film 17A is set to 0.2 nm to 1 nm. The cap film 17A of titanium is formed, for example, by sputtering. Film forming conditions are, for example, as follows:

| | |
|---|---|
| Sputtering gas | Ar |
| Pressure | 1.3 × 10⁻³ Pa to 133 Pa |
| Power | 100 W to 400 W |
| Temperature | room temperature |

As illustrated in FIG. 4B, thermal treatment for the insulating film 16 and cap film 17A is performed in a mixture gas of O₂ and N₂. The thermal treatment conditions are, for example, as follows:

| | |
|---|---|
| Ratio of partial pressure of O₂ to total pressure | 0.1% to 1% |
| Pressure | 13 Pa to 133 Pa |
| Thermal treatment temperature | 400° C. to 800° C. |
| Thermal treatment time | 5 sec to 30 sec |

Ammonia gas may be added to the thermal treatment atmosphere in such a condition that a ratio of a partial pressure of ammonia gas to total pressure is, for example, 0.1% to 1%.

As illustrated in FIG. 4C, since titanium in the cap film 17A diffuses into the insulating film 16, the insulating film 16 and cap film 17A are replaced with a second gate insulating film 18 of HfTiO. If ammonia gas is added to the thermal treatment atmosphere, a second gate insulating film 18 of HfTiON is formed.

The processes after the second gate insulating film 18 is formed are common to the processes of the first embodiment illustrated in FIGS. 1G to 1I.

Also in the second embodiment, the second gate insulating film 18 of HfTiO is formed. It is therefore possible to make small an absolute value of a threshold voltage of pMOSFET, as in the case of the first embodiment.

In the second embodiment, titanium is used as the cap film 17A, and the cap film 17A does not contain oxygen. O₂ is added to the atmosphere gas during thermal treatment illustrated in FIG. 4B in order to prevent generation of defects caused by oxygen deficiency. A ratio of a partial pressure of O₂ to a total pressure is about 0.1% to 1%. It is possible to suppress an increase in a thickness of the first gate insulating film 15 during thermal treatment compared to the case where thermal treatment is performed in an O₂ gas only.

As ammonia gas is added to a thermal treatment atmosphere, the second gate insulating film 18 contains nitrogen so that it is possible to increase a dielectric constant of the second gate insulating film 18 as in the case of the first embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method of manufacturing a semiconductor device, comprising:
forming an insulating film comprising Hf and O over a semiconductor substrate;
forming a cap film comprising oxygen and titanium as constituent elements over the insulating film;
performing thermal treatment to the insulating film and the cap film in a nitrogen gas or noblee gas to diffuse titanium in the cap film into the insulating film to form a gate insulating film; and
forming a gate electrode film over the gate insulating film.

2. The method according to claim 1, wherein the thermal treatment is performed in an atmosphere without oxygen.

3. The method according to claim 1, wherein the thermal treatment is performed in an atmosphere with ammonia.

4. The method according to claim 2, wherein the thermal treatment is performed in an atmosphere with ammonia.

5. The method according to claim 1, wherein the insulating film is made of hafnium oxide not containing Si.

6. The method according to claim 1, further comprising:
patterning the gate insulating film and gate electrode film after the gate electrode film is formed, to form a gate pattern; and
implanting dopant into a surface layer of the semiconductor substrate on either side of a region where the gate pattern is to be disposed to form a source region and a drain region.

7. A method of manufacturing a semiconductor device, comprising:
forming an insulating film comprising Hf and O over a semiconductor substrate;
forming a cap film of titanium over the insulating film;
thermally treating the insulating film and the cap film in an atmosphere containing oxygen gas and ammonia gas to diffuse titanium in the cap film into the insulating film to form a gate insulating film; and
forming a gate electrode film over the gate insulating film.

8. The method according to claim 7, wherein the insulating film is made of hafnium oxide not containing Si.

9. The method according to claim 7, further comprising:
patterning the gate insulating film and gate electrode film after the gate electrode film is formed, to form a gate pattern; and
implanting dopant into a surface layer of the semiconductor substrate on either side of a region where the gate pattern is to be disposed to form a source region and a drain region.
